(19) United States
(12) Patent Application Publication
(10) Pub. No.: US 2008/0013299 A1
(43) Pub. Date: Jan. 17, 2008

(54) Direct Patterning for EMI Shielding and Interconnects Using Miniature Aerosol Jet and Aerosol Jet Array

(75) Inventor: Michael J. Renn, Hudson, WI (US)

Correspondence Address: PEACOCK MYERS, P.C., 201 THIRD STREET, N.W., SUITE 1340, ALBUQUERQUE, NM, 87102, US

(73) Assignee: OPTOMEC, INC., Albuquerque, NM (US)

(21) Appl. No.: 11/779,868

(22) Filed: Jul. 18, 2007

Related U.S. Application Data
(63) Continuation-in-part of application No. 11/302,091, filed on Dec. 12, 2005.
(60) Provisional application No. 60/807,793, filed on Jul. 19, 2006.
(60) Provisional application No. 60/635,847, filed on Dec. 13, 2004.
(60) Provisional application No. 60/669,748, filed on Apr. 8, 2005.

(51) Int. Cl. H05K 9/00

(52) U.S. Cl. 361/818

(57) ABSTRACT

A miniaturized aerosol jet, or an array of miniaturized aerosol jets for direct printing of various aerosolized materials. In the most commonly used embodiment, an aerosol stream is focused and deposited onto a planar or non-planar target, forming a pattern that is thermally or photochemically processed to achieve physical, optical, and/or electrical properties near that of the corresponding bulk material. The apparatus uses an aerosol jet deposition head to form an annularly propagating jet composed of an outer sheath flow and an inner aerosol-laden carrier flow. Miniaturization of the deposition head facilitates the fabrication and operation of arrayed deposition heads, enabling construction and operation of arrays of aerosol jets capable of independent motion and deposition. Arrayed aerosol jets provide an increased deposition rate, arrayed deposition, and multi-material deposition. Applications for the miniaturized aerosol jet or jet array include direct patterning for EMI shielding and interconnects.

### CROSS-REFERENCE TO RELATED APPLICATIONS

This application claims the benefit of the filing of U.S. Provisional Patent Application Ser. No. 60/807,793, entitled “M3D EMI Grid Application,” filed on Jul. 19, 2006. This application is also a continuation in part application of U.S. patent application Ser. No. 11/302,091, entitled “Miniature Aerosol Jet and Aerosol Jet Array,” filed on Dec. 12, 2005, which application claims the benefit of the filing of U.S. Provisional Patent Application Ser. No. 60/635,847, entitled “Miniature Aerosol Jet and Aerosol Jet Array,” filed on Dec. 13, 2004 and U.S. Provisional Patent Application Ser. No. 60/669,748, entitled “Atomizer Chamber and Aerosol Jet Array,” filed on Apr. 8, 2005. The specifications and claims of all said references are incorporated herein by reference.

### BACKGROUND OF THE INVENTION

1. Field of the Invention (Technical Field)

The present invention relates to direct printing of various aerosolized materials using a miniaturized aerosol jet, or an array of miniaturized aerosol jets. The invention more generally relates to maskless, non-contact printing onto planar or non-planar surfaces. The invention may also be used to print materials onto heat-sensitive targets, is performed under atmospheric conditions, and is capable of deposition of sub-micron size features. The present invention may be used to perform direct patterning of EMI shielding, such as grids, and interconnects on planar or non-planar targets.

### SUMMARY OF THE INVENTION

The present invention is a structure for shielding radiation from a target, the structure comprising a target and a plurality of conductive lines directly deposited on the target in a grid pattern, wherein a width of each of the lines is less than approximately 50 microns, preferably less than approximately 12 microns, and optionally less than approximately 1 micron. The lines are optionally substantially transparent to visible radiation. Radiation within a desired wavelength range is preferably transmitted to the target and radiation outside the desired wavelength range is preferably shielded from the target. The target may be planar or non-planar. The structure preferably further comprises an adhesion promoter or an overcoat. The structure preferably comprises an active shield, which preferably broadcasts radiation at one or more desired frequencies. The structure is preferably useful for shielding the target from electromagnetic interference (EMI).

The present invention is also a method for shielding radiation from a target, the method comprising the steps of providing a target, directly depositing on the target a plurality of lines in a grid pattern, each line having a linewidth of less than approximately fifty microns, and shielding unwanted radiation, for example EMI, from the target. The linewidth is preferably less than approximately 12 microns, and optionally less than approximately 1 micron. The method preferably further comprises the step of transmitting radiation within a desired wavelength range to the target and shielding radiation outside said desired wavelength range from the target. The depositing step preferably comprises conformally depositing the lines on a non-planar substrate. The method preferably further comprises the step of varying a height and/or an orientation of a deposition head. The depositing step preferably comprises simultaneously depositing a plurality of lines or line segments. The method optionally further comprises the step of applying an adhesion promoter or an overcoat to the target. The method optionally further comprises the step of broadcasting radiation at one or more desired frequencies.

The present invention is also a deposition head assembly for depositing a material on a target, the deposition head assembly comprising a deposition head comprising a channel for transporting an aerosol comprising the material, one or more inlets for introducing a sheath gas into the deposition head; a first chamber connected to the inlets; a region proximate to an exit of the channel for combining the aerosol with the sheath gas, thereby forming an annular jet comprising an outer sheath flow surrounding an inner aerosol flow; and an extended nozzle. The deposition head assembly preferably has a diameter of less than approximately 1 cm. The inlets are preferably circumferentially arranged around the channel. The region optionally comprises a second chamber.

The first chamber is optionally external to the deposition head and develops a cylindrically symmetric distribution of sheath gas pressure about the channel before the sheath gas is combined with the aerosol. The first chamber is preferably sufficiently long enough to develop a cylindrically symmetric distribution of sheath gas pressure about the channel before the sheath gas is combined with the aerosol. The deposition head assembly optionally further comprises a third chamber for receiving sheath gas from the first chamber, the third chamber assisting the first chamber in developing a cylindrically symmetric distribution of sheath gas pressure about the channel before the sheath gas is combined with the aerosol. The third chamber is preferably connected to the first chamber by a plurality of passages which are parallel to and circumferentially arranged around the channel. The deposition head assembly preferably comprises one or more actuators for translating or tilting the deposition head relative to the target.

The invention is also an apparatus for depositing a material on a target, the apparatus comprising a plurality of channels for transporting an aerosol comprising the material, a sheath gas chamber surrounding the channels, a region proximate to an exit of each of the channels for combining the aerosol with sheath gas, thereby forming an annular jet for each channel, the jet comprising an outer sheath flow surrounding an inner aerosol flow, and an extended nozzle corresponding to each of the channels. The plurality of channels preferably form an array. The aerosol optionally enters each of the channels from a common chamber. The aerosol is preferably individually fed to at least one of the channels. A second aerosolized material is optionally fed to at least one of the channels. The aerosol mass flow rate in at least one of the channels is preferably individually controllable. The apparatus preferably comprises one or more actuators for translating or tilting one or more of the channels and extended nozzles relative to the target.

The apparatus preferably further comprises an atomizer comprising a cylindrical chamber for holding the material, a thin polymer film disposed on the bottom of the chamber, an ultrasonic bath for receiving the chamber and directing ultrasonic energy up through the film, a carrier tube for introducing carrier gas into the chamber, and one or more pickup tubes for delivering the aerosol to the plurality of channels. The carrier tube preferably comprises one or more openings.

The apparatus preferably further comprises a funnel attached to the tube for recycling large droplets of the material. Additional material is optionally continuously provided to the atomizer to replace material which is delivered to the plurality of channels.

An object of the present invention is to provide a miniature deposition head for depositing materials on a target.

An advantage of the present invention is that miniaturized deposition heads are easily incorporated into compact arrays, which allow multiple depositions to be performed in parallel, thus greatly reducing deposition time.

Other objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### A BRIEF DESCRIPTION OF THE DRAWINGS

The accompanying drawings, which are incorporated into and form a part of the specification, illustrate several embodiments of the present invention and, together with the description, serve to explain the principles of the invention. The drawings are only for the purpose of illustrating a preferred embodiment of the invention and are not to be construed as limiting the invention. In the drawings:

FIG. 1a is a cross-section of a miniature deposition head of the present invention;

FIG. 1b displays isometric and cross-sectional views of an alternate miniature deposition head that introduces the sheath gas from six equally spaced channels;

FIG. 1c shows isometric and cross-sectional views of the deposition head of FIG. 1b with an accompanying external sheath plenum chamber;

FIG. 1d shows isometric and a cross-sectional views of a deposition head configuration that introduces the aerosol and sheath gases from tubing that runs along the axis of the head;

FIG. 1e shows isometric and a cross-sectional views of a deposition head configuration that uses internal plenum chambers and introduces the sheath air through a port that connects the head to a mounting assembly;

FIG. 1f shows isometric and cross-sectional views of a deposition head that uses no plenum chambers, providing for the largest degree of miniaturization;

FIG. 2 is a schematic of a single miniaturized deposition head mounted on a movable gantry;

FIG. 3 compares a miniature deposition head to a standard M³D® deposition head;

FIG. 4a is a schematic of the multiplexed head design;

FIG. 4b is a schematic of the multiplexed head design with individually fed nozzles;

FIG. 5a shows the miniature aerosol jet in a configuration that allows the head to be tilted about two orthogonal axes;

FIG. 5b shows an array of piezo-driven miniature aerosol jets;

FIG. 6 shows perspective and cutaway views of the atomizer assembly used with miniature aerosol jet arrays;

FIG. 7 is an optical image of a regular grid pattern on glass as deposited by the M³D process, with tracks that are on a pitch of 0.5 mm;

FIG. 8 shows a close-up image of grid pattern of FIG. 7;

FIG. 9 is a micrograph of conformal deposition of gold ink in an EMI style grid;

FIG. 10 is a photograph of conformal interconnects deposited according to the present invention; and

FIG. 11 shows a close-up image of the interconnects of FIG. 10.

### DESCRIPTION OF THE PREFERRED EMBODIMENTS

### Best Modes for Carrying Out the Invention

Introduction

The present invention generally relates to apparatuses and methods for high-resolution, maskless deposition of liquid and liquid-particle suspensions using aerodynamic focusing. In the most commonly used embodiment, an aerosol stream is focused and deposited onto a planar or non-planar target, forming a pattern that is thermally or photochemically processed to achieve physical, optical, and/or electrical properties near that of the corresponding bulk material. The process is called M³D®, Maskless Mesoscale Material Deposition, and is used to deposit aerosolized materials with linewidths that are an order of magnitude smaller than lines deposited with conventional thick film processes. Deposition is performed without the use of masks. Furthermore, with post-processing laser treatment, the M³D® process is capable of defining lines having widths smaller than 1 micron.

The M³D® apparatus preferably uses an aerosol jet deposition head to form an annularly propagating jet composed of an outer sheath flow and an inner aerosol-laden carrier flow. In the annular aerosol jetting process, the aerosol stream enters the deposition head, preferably either directly after the aerosolization process or after passing through the heater assembly, and is directed along the axis of the device towards the deposition head orifice. The mass throughput is preferably controlled by an aerosol carrier gas mass flow controller. Inside the deposition head, the aerosol stream is preferably initially collimated by passing through a millimeter-size orifice. The emergent particle stream is then preferably combined with an annular sheath gas. The carrier gas and the sheath gas most commonly comprise compressed air or an inert gas, where one or both may contain a modified solvent vapor content. For example, when the aerosol is formed from an aqueous solution, water vapor may be added to the carrier gas or the sheath gas to prevent droplet evaporation.

The sheath gas preferably enters through a sheath air inlet below the aerosol inlet and forms an annular flow with the aerosol stream. As with the aerosol carrier gas, the sheath gas flowrate is preferably controlled by a mass flow controller. The combined streams exit the extended nozzle through an orifice directed at a target. This annular flow focuses the aerosol stream onto the target and allows for deposition of features with dimensions smaller than 1 micron.

In the M³D® method, once the sheath gas is combined with the aerosol stream, the flow does not need to pass through more than one orifice in order to deposit sub-millimeter linewidths. In the deposition of a 10-micron line, the M³D® method typically achieves a flow diameter constriction of approximately 250, and may be capable of constrictions in excess of 1000, for this “single-stage” deposition. No axial constrictors are used, and the flows typically do not reach supersonic flow velocities, thus preventing the formation of turbulent flow, which could potentially lead to a complete constriction of the flow.

Enhanced deposition characteristics are obtained by attaching an extended nozzle to the deposition head. The nozzle is attached to the lower chamber of the deposition head preferably using pneumatic fittings and a tightening nut, and is preferably approximately 0.95 to 1.9 centimeters long. The nozzle reduces the diameter of the emergent stream and collimates the stream to a fraction of the nozzle orifice diameter at distances of approximately 3 to 5 millimeters beyond the nozzle exit. The size of the orifice diameter of the nozzle is chosen in accordance with the range of desired linewidths of the deposited material. The exit orifice typically has a diameter ranging from approximately 50 to 500 microns; however an orifice of any diameter, or comprising an opening of any shape (circular or otherwise), may be used. The deposited linewidth can be approximately as small as one-twentieth the size of the orifice diameter, or as large as the orifice diameter. The use of a detachable extended nozzle also enables the size of deposited structures to be varied from smaller than a micron to as large as a fraction of a millimeter, using the same deposition apparatus. The diameter of the emerging stream (and therefore the linewidth of the deposit) is controlled by the exit orifice size, the ratio of sheath gas flow rate to carrier gas flow rate, and the distance between the orifice and the target. Enhanced deposition can also be obtained using an extended nozzle that is machined into the body of the deposition head. A more detailed description of such an extended nozzle is contained in commonly-owned U.S. patent application Ser. No. 11/011,366, entitled “Annular Aerosol Jet Deposition Using An Extended Nozzle”, filed on Dec. 13, 2004, which is incorporated in its entirety herein by reference.

In many applications, it is advantageous to perform deposition from multiple deposition heads. The use of multiple deposition heads for direct printing applications may be facilitated by using miniaturized deposition heads to increase the number of nozzles per unit area. The miniature deposition head preferably comprises the same basic internal geometry as the standard head, in that an annular flow is formed between the aerosol and sheath gases in a configuration similar to that of the standard deposition head. Miniaturization of the deposition head also facilitates a direct write process in which the deposition head is mounted on a moving gantry, and deposits material on a stationary target.

Miniature Aerosol Jet Deposition Head and Jet Arrays

Miniaturization of the M³D® deposition head may reduce the weight of the device by more than an order of magnitude, thus facilitating mounting and translation on a movable gantry. Miniaturization also facilitates the fabrication and operation of arrayed deposition heads, enabling construction and operation of arrays of aerosol jets capable of independent motion and deposition. Arrayed aerosol jets provide an increased deposition rate, arrayed deposition, and multi-material deposition. Arrayed aerosol jets also provide for increased nozzle density for high-resolution direct write applications, and can be manufactured with customized jet spacing and configurations for specific deposition applications. Nozzle configurations include, but are not limited to, linear, rectangular, circular, polygonal, and various nonlinear arrangements.

The miniature deposition head functions similarly, if not identically, to the standard deposition head, but has a diameter that is approximately one-fifth the diameter of the larger unit. Thus the diameter or width of the miniature deposition head is preferably approximately 1 cm, but could be smaller or larger. The several embodiments detailed in this application disclose various methods of introducing and distributing the sheath gas within the deposition head, as well as methods of combining the sheath gas flow with the aerosol flow. Development of the sheath gas flow within the deposition head is critical to the deposition characteristics of the system, determines the final width of the jetted aerosol stream and the amount and the distribution of satellite droplets deposited beyond the boundaries of the primary deposit, and minimizes clogging of the exit orifice by forming a barrier between the wall of the orifice and the aerosol-laden carrier gas.

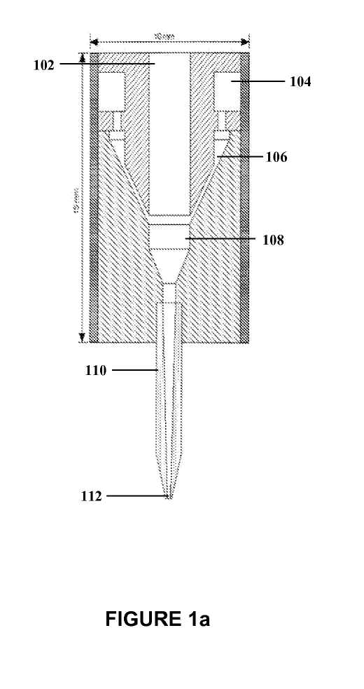

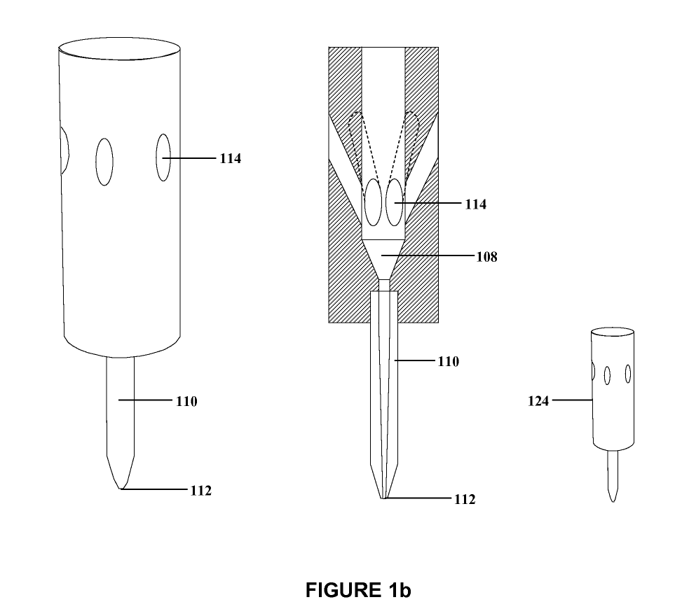

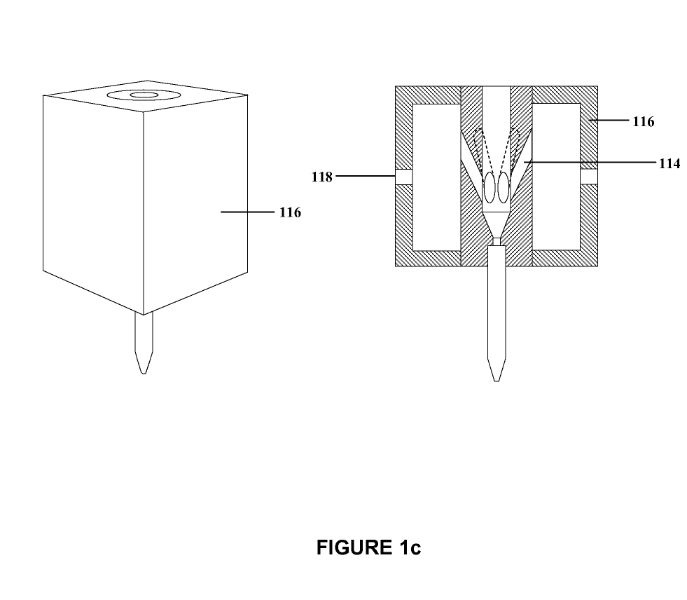

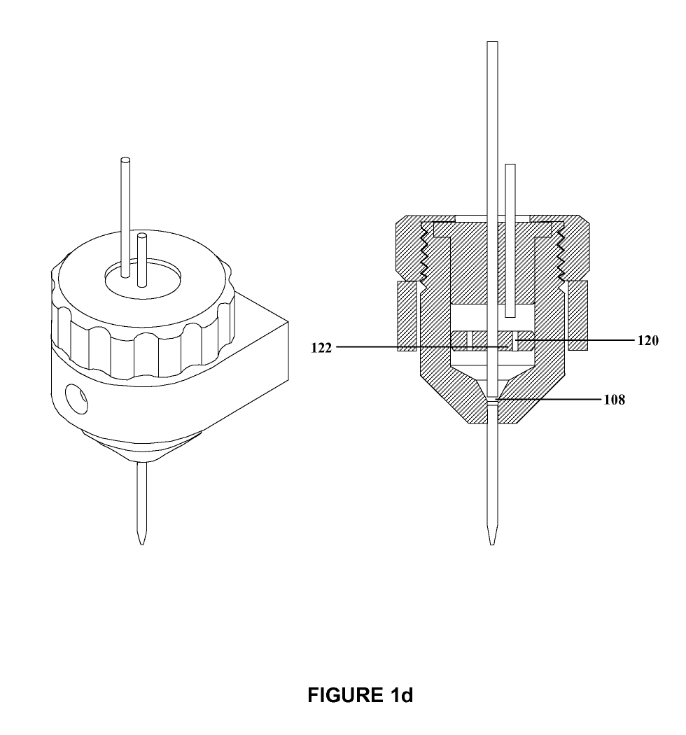

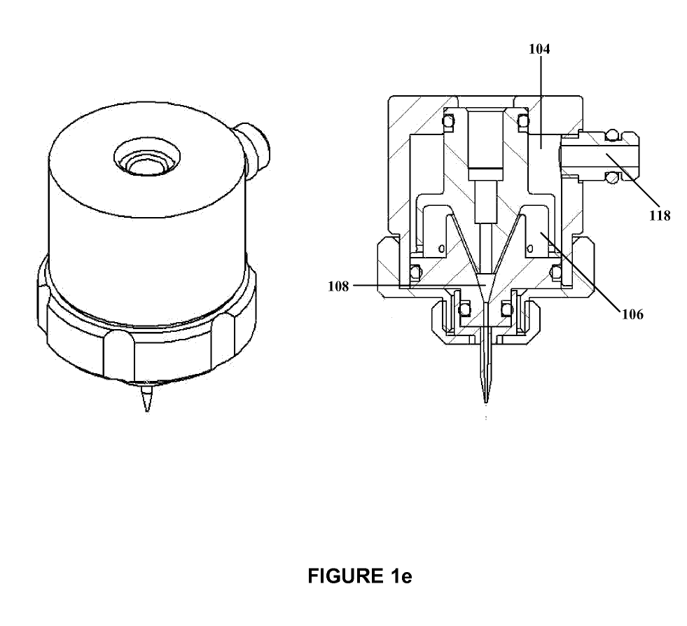

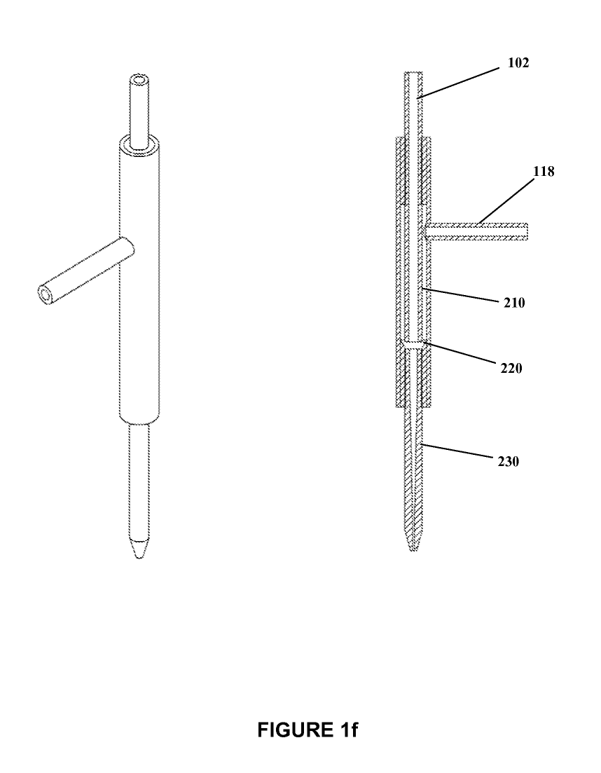

A cross-section of a miniature deposition head is shown in FIG. 1a. An aerosol-laden carrier gas enters the deposition head through aerosol port 102, and is directed along the axis of the device. An inert sheath gas enters the deposition head laterally through ports connected to upper plenum chamber 104. The plenum chamber creates a cylindrically symmetric distribution of sheath gas pressure about the axis of the deposition head. The sheath gas flows to conical lower plenum chamber 106, and is combined with the aerosol stream in a combination chamber 108, forming an annular flow consisting of an inner aerosol-laden carrier gas flow and an outer inert sheath gas flow. The annular flow is propagated through an extended nozzle 110, and exits at the nozzle orifice 112.

FIG. 1b shows an alternate embodiment in which the sheath gas is introduced from six equally spaced channels. This configuration does not incorporate the internal plenum chambers of the deposition head pictured in FIG. 1a. Sheath gas channels 114 are preferably equally spaced about the axis of the device. The design allows for a reduction in the size of the deposition head 124, and easier fabrication of the device. The sheath gas combines with the aerosol carrier gas in combination chamber 108 of the deposition head. As with the previous design, the combined flow then enters an extended nozzle 110 and exits from the nozzle orifice 112. Since this deposition head comprises no plenum chambers, a cylindrically symmetric distribution of sheath gas pressure is preferably established before the sheath gas is injected into the deposition head. FIG. 1c shows a configuration for developing the required sheath gas pressure distribution using external plenum chamber 116. In this configuration, the sheath gas enters the plenum chamber from ports 118 located on the side of the chamber, and flows upward to the sheath gas channels 114.

FIG. 1d shows isometric and cross-sectional views of a deposition head configuration that introduces the aerosol and sheath gases from tubing that runs along the axis of the head. In this configuration, a cylindrically symmetric pressure distribution is obtained by passing the sheath gas through preferably equally spaced holes 120 in disk 122 centered on the axis of the head. The sheath gas is then combined with the aerosol carrier gas in a combination chamber 108.

FIG. 1e shows isometric and cross-sectional views of a deposition head configuration of the present invention that uses internal plenum chambers, and introduces the sheath air through a port 118 that preferably connects the head to a mounting assembly. As in the configuration of FIG. 1a, the sheath gas enters an upper plenum chamber 104 and then flows to a lower plenum chamber 106 before flowing to a combination chamber 108. However in this case, the distance between the upper and lower plenum chambers is reduced to enable further miniaturization of the deposition head.

FIG. 1f shows isometric and cross-sectional views of a deposition head that uses no plenum chambers, providing for the largest degree of miniaturization. The aerosol enters sheath gas chamber 210 through an opening in the top of aerosol tube 102. The sheath gas enters the head through input port 118, which is optionally oriented perpendicularly to aerosol tube 102, and combines with the aerosol flow at the bottom of aerosol tube 102. Aerosol tube 102 may extend partially or fully to the bottom of sheath gas chamber 210. The length of sheath gas chamber 210 should be sufficiently long to ensure that the flow of the sheath gas is substantially parallel to the aerosol flow before the two combine, thereby generating a preferably cylindrically symmetric sheath gas pressure distribution. The sheath gas is then combined with the aerosol carrier gas at or near the bottom of sheath gas chamber 210 and the combined gas flows are directed into extended nozzle 230 by converging nozzle 220.

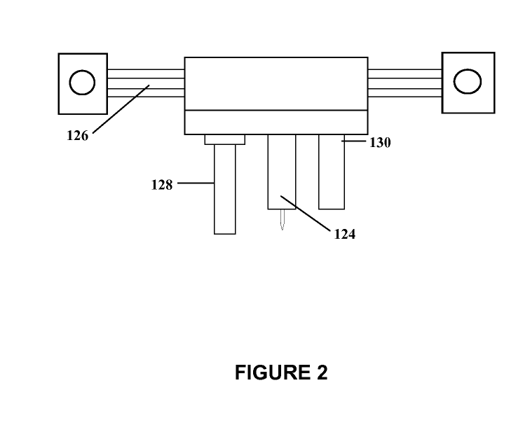

FIG. 2 shows a schematic of a single miniaturized deposition head 124 mounted on a movable gantry 126. The system preferably includes an alignment camera 128 and a processing laser 130. The processing laser can be a fiber-based laser. In this configuration, recognition and alignment, deposition, and laser processing are performed in a serial fashion. The configuration significantly reduces the weight of the deposition and processing modules of the M³D® system, and provides an inexpensive solution to the problem of maskless, non-contact printing of mesoscale structures.

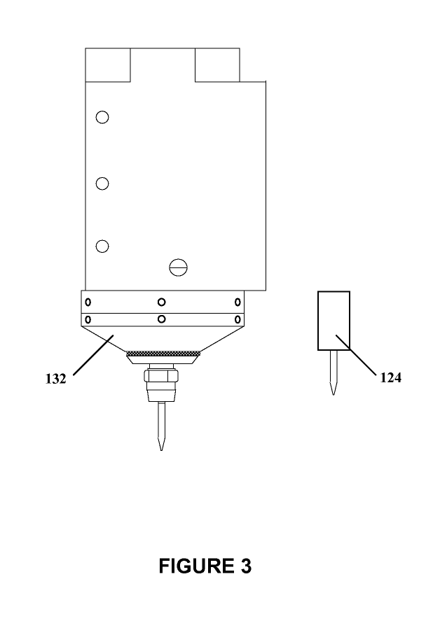

FIG. 3 displays standard M³D® deposition head 132 side by side with miniature deposition head 124. Miniature deposition head 124 is approximately one-fifth the diameter of standard deposition head 132.

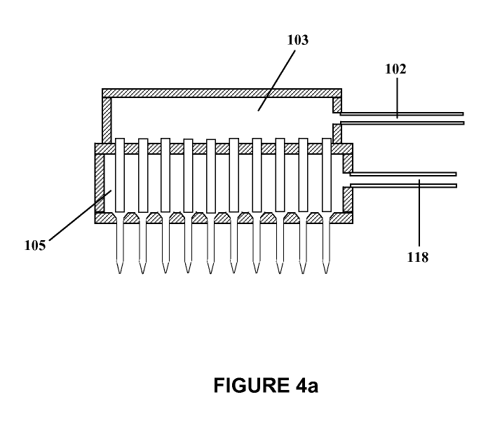

Miniaturization of the deposition head enables fabrication of a multiplexed head design. A schematic of such a device is shown in FIG. 4a. In this configuration, the device is monolithic, and the aerosol flow enters aerosol plenum chamber 103 through aerosol gas port 102 and then enters an array of ten heads, although any number of heads may be used. The sheath gas flow enters sheath plenum chamber 105 through at least one sheath gas port 118. In this monolithic configuration, the heads deposit one material simultaneously, in an arrayed fashion. The monolithic configuration can be mounted on a two-axis gantry with a stationary target, or the system can be mounted on a single axis gantry, with a target fed in a direction orthogonal to the motion of the gantry.

FIG. 4b shows a second configuration for a multiplexed head. The figure shows ten linearly-arrayed nozzles (although any number of nozzles may be arrayed in any one or two dimensional pattern), each being fed by individual aerosol port 134. The configuration allows for uniform mass flow between each nozzle. Given a spatially uniform atomization source, the amount of aerosol delivered to each nozzle is dependent on the mass flowrate of the flow controller or flow controllers, and is independent of the position of the nozzle in the array. The configuration of FIG. 4b also allows for deposition of more than one material from a single deposition head. These different materials may optionally be deposited simultaneously or sequentially in any desired pattern or sequence. In such an application, a different material may be delivered to each nozzle, with each material being atomized and delivered by the same atomization unit and controller, or by individual atomization units and controllers.

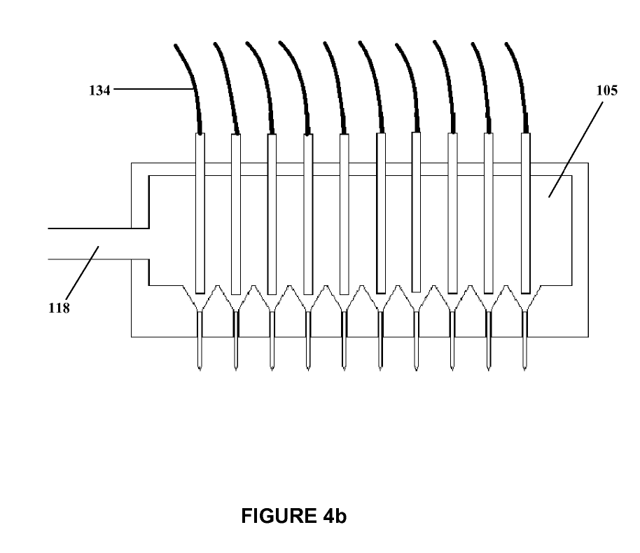

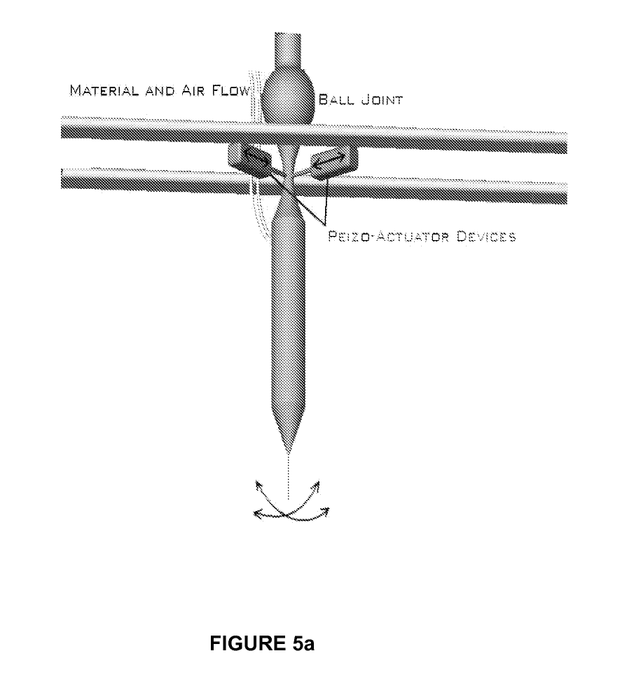

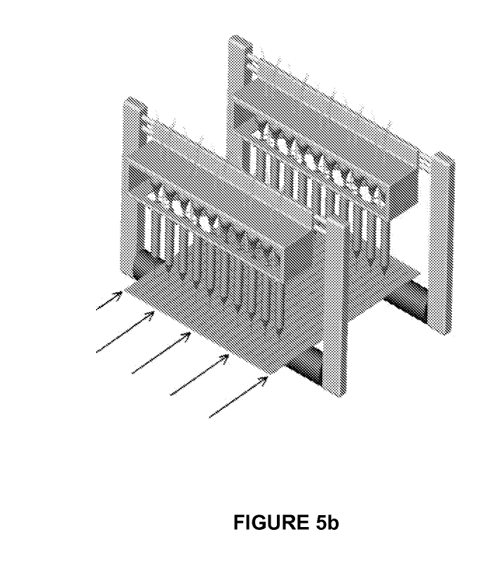

FIG. 5a shows a miniature aerosol jet in a configuration that allows the head to be tilted about two orthogonal axes. FIG. 5b is a representation of an array of piezo-driven miniature aerosol jets. The array is capable of translational motion along one axis. The aerosol jets are preferably attached to a bracket by flexure mountings. The heads are tilted by applying a lateral force using a piezoelectric actuator, or alternatively by actuating one or more (preferably two) galvanometers. The aerosol plenum can be replaced with a bundle of tubes each feeding an individual depositing head. In this configuration, the aerosol jets are capable of independent deposition.

Atomizer Chamber for Aerosol Jet Array

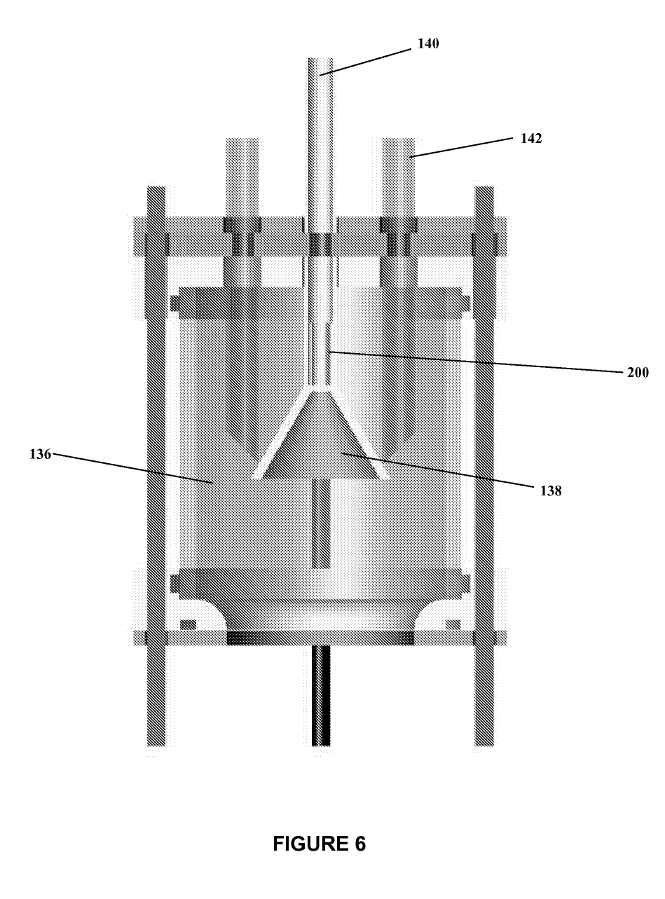

An aerosol jet array requires an atomizer that is significantly different from the atomizer used in a standard M³D® system. FIG. 6 shows a cutaway view of an atomizer that has a capacity sufficient to feed aerosolized mist to ten or more arrayed or non-arrayed nozzles. The atomizer assembly comprises an atomizer chamber 136, preferably a glass cylinder, on the bottom of which is preferably disposed a thin polymer film which preferably comprises Kapton®. The atomizer assembly is preferably set inside an ultrasonic atomizer bath with the ultrasonic energy directed up through the film. This film transmits the ultrasonic energy to the functional ink, which is then atomized to generate an aerosol.

Containment funnel 138 is preferably centered within atomizer chamber 136 and is connected to carrier gas port 140, which preferably comprises a hollow tube that extends out of the top of the atomizer chamber 136. Port 140 preferably comprises one or more slots or notches 200 located just above funnel 138, which allow the carrier gas to enter chamber 136. Funnel 138 contains the large droplets that are formed during atomization and allows them to downward along the tube to the bath to be recycled. Smaller droplets are entrained in the carrier gas, and delivered as an aerosol or mist from the atomizer assembly via one or more pickup tubes 142 which are preferably mounted around funnel 138.

The number of aerosol outputs for the atomizer assembly is preferably variable and depends on the size of the multi-nozzle array. Gasket material is preferably positioned on the top of the atomizer chamber 136 as a seal and is preferably sandwiched between two pieces of metal. The gasket material creates a seal around pickup tubes 142 and carrier gas port 140. Although a desired quantity of material to be atomized may be placed in the atomization assembly for batch operation, the material may be continuously fed into the atomizer assembly, preferably by a device such as a syringe pump, through one or more material inlets which are preferably disposed through one or more holes in the gasket material. The feed rate is preferably the same as the rate at which material is being removed from the atomizer assembly, thus maintaining a constant volume of ink or other material in the atomization chamber.

Shuttering and Aerosol Output Balancing

Shuttering of the miniature jet or miniature jet arrays can be accomplished by using a pinch valve positioned on the aerosol gas input tubing. When actuated, the pinch valve constricts the tubing, and stops the flow of aerosol to the deposition head. When the valve is opened, the aerosol flow to the head is resumed. The pinch valve shuttering scheme allows the nozzle to be lowered into recessed features and enables deposition into such features, while maintaining a shuttering capability.

In addition, in the operation of a multinozzle array, balancing of the aerosol output from individual nozzles may be necessary. Aerosol output balancing may be accomplished by constricting the aerosol input tubes leading to the individual nozzles, so that corrections to the relative aerosol output of the nozzles can be made, resulting in a uniform mass flux from each nozzle.

Further applications involving a miniature aerosol jet or aerosol jet array include, but are not limited to, large area printing, arrayed deposition, multi-material deposition, and conformal printing onto 3-dimensional objects using ⅘ axis motion.

EMI Grid Shield Applications

A regular conducting grid pattern is often used to provide an effective EMI shield for certain applications. The ability to produce complex and compact parts with such a shielding capability is emerging as a requirement for some of the latest technologies, such as military equipment. To do this, it is typically necessary to imprint the conducting grid-shielding pattern onto these parts. On parts having complex shapes, for example the inside of a hemispherical dome, there have been few effective methods to do this imprinting.

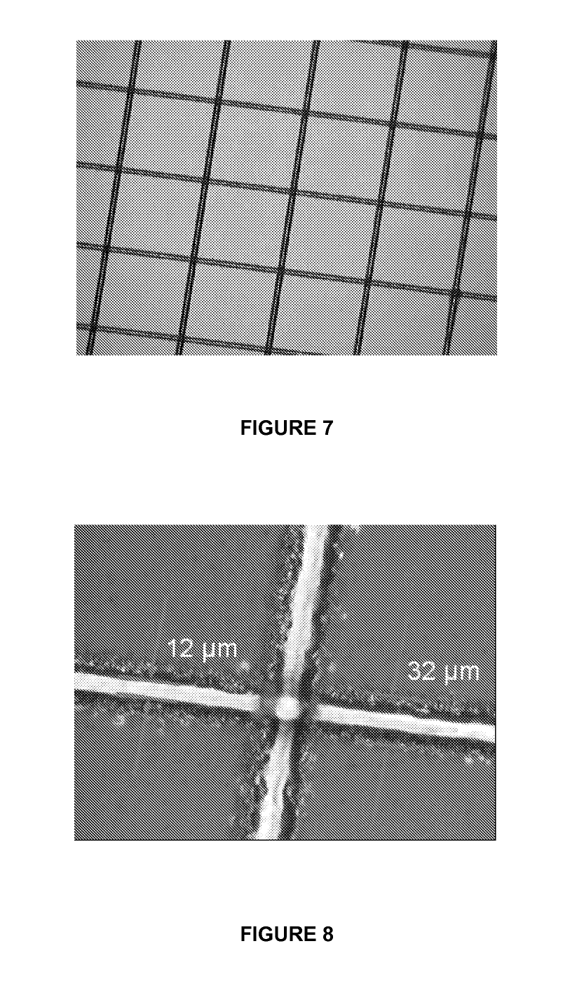

The present invention, using a single M³D® deposition head, or the multi-jet array described above, has the capability to produce low-resistivity grid structures in flat or three-dimensional surfaces. FIGS. 7 and 8 are an example of such a low-resistivity grid structure. The 0.5 mm pitch grid was deposited on a glass substrate. The line thickness was measured to be approximately 8.2 microns, with a line width of approximately 12 microns and overspray extending to about 32 microns. Lines of any thickness and width, even below one micron, may be deposited according to the present invention. When using the M³D deposition head in either configuration to write on three-dimensional surfaces, the deposition head can be integrated into standard robot-positioning systems or with other multi-axes motion control systems, to achieve such three-dimensional depositions with accuracy and repeatability.

Material compatibility is an important issue for the M³D process. While many combinations of deposition material and substrates are compatible, certain combinations require other elements such as surface treatments (i.e. solvent, plasma, etc.) or curing of the deposited material (i.e. heat, lamp, laser, etc.).

Planar Grids

EMI shields are typically used to protect sensitive circuitry from unwanted radio frequency and microwave radiation. A simple, low cost, EMI shield consists of a continuous metal film that is either held in close proximity to or wrapped around the circuitry. The shield attenuates RF radiation as the incoming radiation induces currents inside the shield. These currents, in turn, generate fields that cancel the incoming radiation. This is similar to the operation of a Faraday cage, in which both static and RF fields are prevented from penetrating into the cage region. If the metal film is sufficiently thick and has sufficient conductivity, nearly all incoming RF radiation, regardless of frequency, can be blocked. However, if the metal film is thin or the conductivity is poor, then a significant amount of radiation will pass through the film.

While metal sheets and films are very efficient at blocking unwanted RF, they also block visible light. In many cases it is desirable to block the RF but maintain transparency at visible frequencies. Transparent EMI shields can be made from thin films of several materials including transparent conducting oxides (e.g. ITO), thin metal films (e.g. silver and gold), transparent conducting polymers (e.g. PEDOT), or multilayer stacks of metal and dielectric films. These shields are generally designed to block all RF frequencies and to allow visible transmission. However, some of the multilayer shields will also pass certain infrared frequencies. The methods used to fabricate transparent shields consist primarily of vacuum deposition techniques such as sputtering and vapor deposition. These approaches are generally more expensive than metal films, especially at low volume.

In contrast to continuous conductive films, an alternative approach to fabricating EMI shields is with conductive grids or mesh. In general, grids are effective at shielding RF having wavelengths that are larger than the grid openings. Smaller wavelengths are not significantly attenuated. Consequently, it is possible to fabricate shields that are nearly transparent to visible light (short wavelength), yet efficient at blocking incoming RF (large wavelength). The grids also typically become more transparent as the size scale of the conducting elements is reduced. Conductors at the 50 micron size scale are considered to be transparent, but 10 micron wide conducting elements and smaller are usually preferred. Transparent EMI shields are typically required for plasma displays and microwave ovens.

EMI grid shields are generally more complicated to fabricate than continuous film shields because of the need to form patterns. Methods for forming such patterns include shadow masking, photolithography, and various direct printing methods. However, the masking techniques tend to be wasteful and expensive. Consequently, the M³D process of the present invention is a low cost, green approach alternative to printing EMI grids. The direct patterning is preferably accomplished by printing conductive inks into the desired pattern and then curing the inks to make the features conductive. Ink jetting and screen printing can produce conductive features at the 50 micron size scale. The M³D process can print the features to less than 1 micron. Furthermore, the M³D process can create the grid patterns without the need for masks, resulting in little materials waste. Multinozzle M³D printheads have higher throughput with higher metals loading than ink jet, and with smaller feature sizes.

Non-Planar Grids

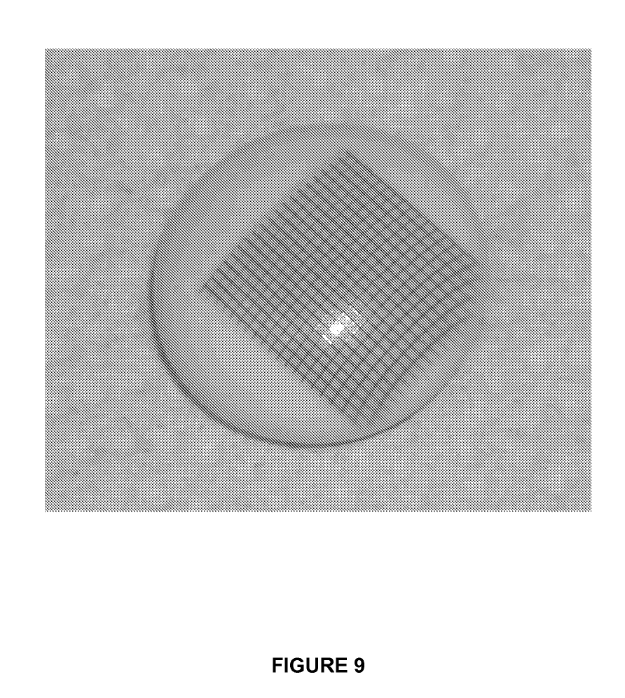

While thin metal and transparent conductive films can be wrapped around a 3D object to provide EMI protection, such approaches are not always practical. The films may need to be attached to the 3D surface with adhesives, which can fail depending on operating and environmental conditions. The films can also wrinkle and buckle, among other problems. A direct printing approach, such as the M³D process of the present invention, allows the EMI grid to be printed directly onto the 3D surface. FIG. 9 shows an example of conformal deposition of gold ink in an EMI style grid on a non-planar substrate. The z-height and/or orientation of the deposition head is optionally varied during deposition to maximize the quality of the deposit. If necessary, adhesion promoters can be sprayed on or locally deposited to enhance the durability of the printed grid. Similarly, overcoat materials, such as polyurethane, can be sprayed on or locally deposited over the grid to provide further protection against the operating environment.

Planar Frequency Selective Shields

Continuous metal films will attenuate RF at all frequencies and the grids will attenuate RF frequencies, but not all visible frequencies are passed. In some cases it is desirable to allow certain frequencies to pass, but attenuate all others. Such frequency selective shields are useful for protecting sensitive circuits from unwanted RF, but allowing certain frequencies, such as communication frequencies, to pass. For example, it would be advantageous to incorporate an EMI shield into an automotive windshield to block unwanted RF, but allow cell phone signals to pass. Occupants inside the automobile would then be able to communicate with cell phones. Similarly, a facility that is broadcasting a WiFi signal for its user network may wish to shield the facility from the outside world for security purposes. But the users may need to use cell phones, so the shield could be designed to block WiFi signals, but pass the cell phone signals.

Frequency selective shields consist of patterned conductors that are designed to absorb most frequencies, but pass certain discrete frequencies. These shields can be made by traditional patterning methods, such as photolithography or shadow masking, but these methods are expensive. They can also be printed with ink jet or screen printing, but these methods result in larger, less transparent features. An advantage of the M³D process is its capability to print arbitrary conductive features down to a less than 1 micron size scale.

Non-Planar Frequency Selective Shields

Like the non-planar grids, the same advantages hold in relation to directly printing frequency-selective patterns on a 3D surface. The shields are more robust and cost effective compared to films that are attached by adhesives. Commercial examples of printed frequency selective shields include the windshields on an aircraft. The shield will block unwanted RF from the outside environment while allowing communication signals from inside the aircraft to pass.

Active Shields

The above-described shields are all passive in the sense that they attenuate RF due to the induced currents from the incoming radiation. However, a shield can be designed to actively broadcast RF at frequencies that would cancel the incoming frequencies. This is analogous to noise suppression circuitry that is commonly applied in hearing aid devices. An active shield would incorporate antenna structures and complimentary drive circuitry to emit RF in response to incoming signals. The advantage of active shielding over passive shielding is that the RF can be blocked more efficiently and completely. For example, the passive shields attenuate RF to a level depending on the conductive film thickness and conductivity. A certain amount of RF can penetrate a passive shield, whereas an active shield can completely cancel the incoming RF. An active shield may also be designed by combining both passive shielding elements and active elements. This hybrid shield could possibly be used to broadcast at communication frequencies, but attenuate at all other frequencies.

Wire-Bond Replacement and Other Interconnects

Conventional wire-bonding techniques require a loop of wire that will add to the total height of the device. In addition, this loop of wire will form an inductive loop degrading high-frequency performance and increasing noise levels. The M³D process eliminates the inductive loop of wire, thus reducing the total height of the device. By writing directly from contact pads on the die to the substrate or substrate pads, the loop area is almost completely eliminated. In addition, such zero profile interconnects are more mechanically robust and reliable. In cases where the bond-wire loop is problematic, for example in magnetic field sensors where the standoff height must be minimized, the M³D process offers an alternative to wire bonding. In addition, for high-frequency applications, the wire-loop area can be the limiting factor on bandwidth; the M³D process has the potential to push the bandwidth of such devices out significantly by limiting the parasitic inductance associated with a loop of wire, thus reducing or eliminating antenna effects.

The M³D process is useful not only for applications currently served by wire bonding but also for general interconnection problems. The M³D process can be used to connect surface mount components directly to a substrate, such as a PCB, without the use of solder. High density, custom or conformal connectors and interconnections can also be fabricated. The M³D process can also write on three-dimensional surfaces and various non-traditional substrate materials such as moldable plastics. Consequently, the M³D process can be used to apply interconnections to chips mounted on 3D surfaces and various substrates. For example, a surface mount device could be attached to the surface of a molded plastic shell and the M³D process could then be used to write electrical conductors from the device to other mounted or embedded devices on the shell.

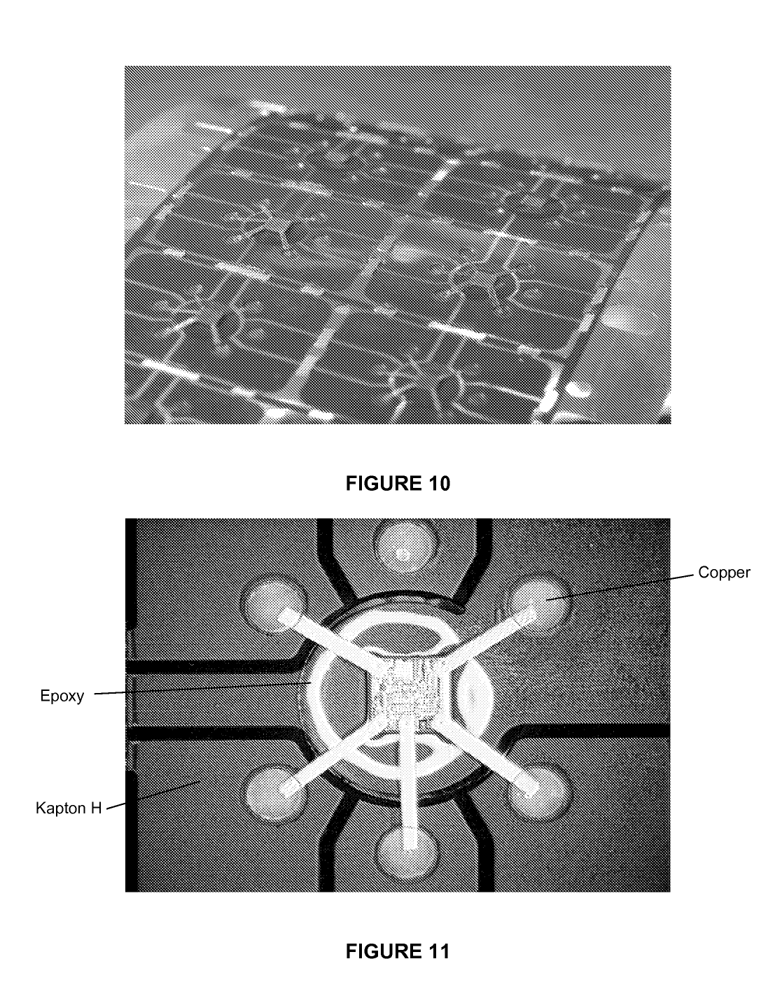

An example of this is shown in FIGS. 10 and 11. A chip to substrate (pad) silver interconnect comprising a 150 micron wide ribbon having a 1 Ohm resistance was deposited over an epoxy bump on a Kapton H substrate. However, any size interconnect having any desired resistance can be fabricated on any desired substrate. The M³D process can also be used to directly write devices on non-traditional substrates, such as antennae or sensors, and then write connections from the written device to a surface mount controller chip. A specific example is the printing of an RF tag on a plastic shell. The M³D process can be used to print the antenna and then to connect the antenna to an RF tag chip set. The completed tag may then be embedded in a plastic shell by, for example, laminating an overlay.

Although the present invention has been described in detail with reference to particular preferred and alternative embodiments, persons possessing ordinary skill in the art to which this invention pertains will appreciate that various modifications and enhancements may be made without departing from the spirit and scope of the Claims that follow, and that other embodiments can achieve the same results. The various configurations that have been disclosed above are intended to educate the reader about preferred and alternative embodiments, and are not intended to constrain the limits of the invention or the scope of the Claims. Variations and modifications of the present invention will be obvious to those skilled in the art, and it is intended to cover all such modifications and equivalents. The entire disclosures of all patents and publications cited above are hereby incorporated by reference.

1. A structure for shielding radiation from a target, the structure comprising:
a target; and
a plurality of conductive lines directly deposited on said target in a grid pattern;
wherein a width of each of said lines is less than approximately 50 microns.

2. The structure of claim 1 wherein said width is less than approximately 12 microns.

3. The structure of claim 2 wherein said width is less than approximately 1 micron.

4. The structure of claim 1 wherein said lines are substantially transparent to visible radiation.

5. The structure of claim 1 wherein radiation within a desired wavelength range is transmitted to the target and radiation outside said desired wavelength range is shielded from said target.

6. The structure of claim 1 wherein said target is planar or non-planar.

7. The structure of claim 1 further comprising an adhesion promoter or an overcoat.

8. The structure of claim 1 comprising an active shield.

9. The structure of claim 8 wherein said shield broadcasts radiation at one or more desired frequencies.

10. The structure of claim 1 useful for shielding said target from electromagnetic interference (EMI).

11. A method for shielding radiation from a target, the method comprising the steps of:
providing a target;
directly depositing on the target a plurality of lines in a grid pattern, each line having a linewidth of less than approximately fifty microns; and
shielding unwanted radiation from the target.

12. The method of claim 11 wherein the linewidth is less than approximately 12 microns.

13. The method of claim 12 wherein the linewidth is less than approximately 1 micron.

14. The method of claim 11 further comprising the step of transmitting radiation within a desired wavelength range to the target and shielding radiation outside said desired wavelength range from the target.

15. The method of claim 11 wherein the depositing step comprises conformally depositing the lines on a non-planar target.

16. The method of claim 11 further comprising the step of varying a height and/or an orientation of a deposition head.

17. The method of claim 11 wherein the depositing step comprises simultaneously depositing a plurality of lines or line segments.

18. The method of claim 11 further comprising the step of applying an adhesion promoter or an overcoat to the target.

19. The method of claim 11 further comprising the step of broadcasting radiation at one or more desired frequencies.

20. The method of claim 11 wherein the unwanted radiation comprises EMI.

21. The structure of claim 6 wherein said target comprises a three-dimensional surface.

22. The structure of claim 6 wherein said lines have been conformally deposited on said target.

23. The method of claim 15 wherein said target comprises a three-dimensional surface.

24. The method of claim 16 wherein the varying step comprising tilting and/or translating a deposition head with respect to the target.

25. The method of claim 24 wherein the depositing step comprises conformally depositing the lines on a three-dimensional surface.
